(19) United States
(12) Patent Application Publication
(10) Pub. No.: US 2025/0275067 A1
(43) Pub. Date: Aug. 28, 2025

(54) DISPLAY DEVICE

(71) Applicant: LG Display Co., Ltd., Seoul (KR)

(72) Inventors: SangHoon OH, Paju-si (KR); HyeongMin JEON, Paju-si (KR); Heeyeon HWANG, Paju-si (KR)

(73) Assignee: LG Display Co., Ltd., Seoul (KR)

(21) Appl. No.: 19/028,680

(22) Filed: Jan. 17, 2025

(30) Foreign Application Priority Data
Feb. 28, 2024 (KR) 10-2024-0029131

(51) Int. Cl. H05K 5/02; B32B 5/02; B32B 15/04; B32B 17/06; B32B 27/06; D03D 1/00; D03D 13/00

(52) U.S. Cl. CPC H05K 5/02; B32B 5/024; B32B 15/04; B32B 17/06; B32B 27/06; D03D 1/0088; D03D 13/008; B32B 2260/021; B32B 2260/046; B32B 2307/42; B32B 2307/546; B32B 2457/20

(57) ABSTRACT

A display apparatus can include a display panel having a non-bending area and a bending area adjacent to the non-bending area, and a support member located below the display panel and including a plurality of fiber bundles and a resin surrounding the plurality of fiber bundles. The plurality of fiber bundles are woven to have a first pattern in the non-bending area and are woven to have a second pattern in at least a partial area of the bending area. Further, at least one of a weave form or a fiber density of the first pattern is different from at least one of a weave form or a fiber density of the second pattern. As such, it is possible to prevent wrinkles even without a micro-patterning process when bending the display apparatus.

### CROSS-REFERENCE TO RELATED APPLICATION

This application claims priority to Korean Patent Application No. 10-2024-0029131, filed in the Republic of Korea on Feb. 28, 2024, the entire contents of which is hereby expressly incorporated by reference for all purposes as if fully set forth herein into the present application.

### BACKGROUND

### Field

Embodiments of the present disclosure relate to a display apparatus and a method for manufacturing the same.

### Description of the Related Art

Recently, as the use of a display panel such as an LCD (liquid crystal display), an OLED (organic light emitting diode) and a PDP (plasma display panel) is generalized, attempts are being made to increase the ratio of an area where an image is implemented in an image display apparatus using the display panel.

In order to increase the ratio of an area where an image is implemented, the area of a bezel area where an image is not implemented needs to be reduced. However, since it is impossible to completely eliminate the bezel area, a limitation exists in increasing this ratio.

In this consideration, a display apparatus is being developed, in which, instead of reducing the size of a bezel area, a display panel is bent in the bezel area so that the bezel area is not visible.

However, when the display panel is bent, a problem can arise in that, due to a spring-back phenomenon, components included in the display apparatus can be separated from each other or bubbles can be generated.

Although a micro-patterning process is performed to prevent wrinkles that can occur in an area where the display panel is bent, a limitation is likely to be caused in that a process can be complicated and can take a long time.

### SUMMARY OF THE DISCLOSURE

Embodiments of the present disclosure are directed to providing a display apparatus capable of preventing or minimizing wrinkles even without a micro-patterning process when bending the display apparatus.

Embodiments of the present disclosure are directed to providing a display apparatus capable of preventing or minimizing components included in the display apparatus from being separated from each other or bubbles from being generated due to a spring-back phenomenon when bending the display apparatus.

According to embodiments of the present disclosure, a display apparatus can include a display panel including a non-bending area and a bending area adjacent to the non-bending area; and a support member located below the display panel and including a plurality of fiber bundles and a resin surrounding the plurality of fiber bundles, wherein the plurality of fiber bundles are woven to have a first pattern in the non-bending area and are woven to have a second pattern in at least a partial area of the bending area and at least one of a weave form or a fiber density of the first pattern is different from at least one of a weave form or a fiber density of the second pattern.

According to embodiments of the present disclosure, a display apparatus can include a display panel including a first area and a second area adjacent to the first area; and a support member disposed on a back surface of the display panel and including a plurality of fiber bundles, wherein the plurality of fiber bundles are woven in a first pattern in an area overlapping the first area and are woven in a second pattern in an area overlapping at least a part of the second area, wherein the first pattern and the second pattern are different weave type or the plurality of fiber bundles included in the first pattern and the plurality of fiber bundles included in the second pattern have different density.

According to the embodiments of the present disclosure, it is possible to provide a display apparatus capable of preventing or minimizing wrinkles even without a micro-patterning process when bending the display apparatus.

According to the embodiments of the present disclosure, it is possible to provide a display apparatus capable of preventing or minimizing components included in the display apparatus from being separated from each other or bubbles from being generated due to a spring-back phenomenon when bending the display apparatus.

According to the embodiments of the present disclosure, since a separate micro-patterning process for controlling wrinkles when bending a display apparatus is not required, it is possible to provide a display apparatus having process optimization.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a view illustrating an example of the cross-sectional structure of a display apparatus according to embodiments of the present disclosure.

FIG. 2 is a view illustrating a part of the cross-sectional structure illustrated in FIG. 1.

FIG. 3 is a view illustrating another example of the cross-sectional structure of the display apparatus according to the embodiments of the present disclosure.

FIG. 4 is a view three-dimensionally illustrating a part of the cross-sectional structure illustrated in FIG. 3.

FIG. 5 is a view illustrating an example of a cross-sectional structure taken along a line I-I′ of FIG. 4.

FIG. 6 is a view illustrating an example of the planar structure of a configuration illustrated in (a) of FIG. 5.

FIG. 7 is a view illustrating another example of the cross-sectional structure taken along the line I-I′ of FIG. 4.

FIG. 8 is a view illustrating an example of the planar structure of a configuration illustrated in (a) of FIG. 7.

FIG. 9 is a view illustrating an example of a cross-sectional structure taken along a line II-II' of FIG. 4.

FIG. 10 is a view illustrating an example of the planar structure of a configuration illustrated in (a) of FIG. 9.

FIG. 11 is a view illustrating another example of the cross-sectional structure taken along the line II-II' of FIG. 4.

FIG. 12 is a view illustrating an example of the planar structure of a configuration illustrated in (a) of FIG. 11.

FIGS. 13A and 13B are views illustrating examples of changes in the cross-sectional and planar structures of the display apparatus when the display apparatus is bent.

FIG. 14 is a view illustrating an example of a method for manufacturing a display apparatus according to embodiments of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including,” “having,” “containing,” “constituting,” “make up of” and “formed of”' used herein are generally intended to allow other components to be added unless the terms are used with the term “only.” As used herein, singular forms are intended to include plural forms unless the context clearly indicates otherwise.

Terms, such as “first,” “second,” “A,” “B,” “(A)” or “(B)” can be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element can be included in at least one of two or more elements that “are connected or coupled to,” “contact or overlap,” etc. each other.

When time relative terms, such as “after,” “subsequent to,” “next,” “before” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “can.”

Hereinafter, various embodiments of the present disclosure will be described in detail with reference to accompanying drawings. All the components of each display apparatus according to all embodiments of the present disclosure are operatively coupled and configured.

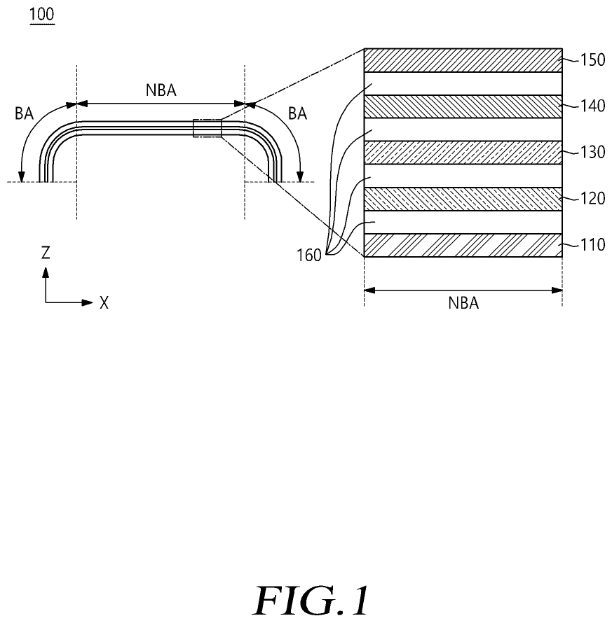

FIG. 1 is a view illustrating an example of the cross-sectional structure of a display apparatus according to embodiments of the present disclosure.

Referring to FIG. 1, a display apparatus 100 can include a support layer 110, a back plate 120, a display panel 130, a polarizer 140, a cover glass 150 and an adhesive layer 160.

The support layer 110 can play a role of supporting the display apparatus 100. The support layer 110 can be formed of metal. However, the support layer 110 is not limited thereto. The support layer 110 can be formed of plastic. For example, the support layer 110 can be polyimide (PI).

The back plate 120 can be disposed on the support layer 110. The back plate 120 can play a role of maintaining the rigidity of the display panel 130 and preventing foreign substances from being attached to the underside of the display panel 130.

The back plate 120 can be formed of a material with high rigidity, such as plastic or metal, to maintain the rigidity of the display panel 130.

The display panel 130 can be disposed on the back plate 120. The display panel 130 can be a layer in which a plurality of subpixels are formed and transistors for driving the plurality of subpixels and so on are formed. The display panel 130 can be an organic light emitting display panel (OLED), but is not limited thereto.

The polarizer 140 can be disposed on the display panel 130. The polarizer 140 can prevent external light from being reflected inside the display apparatus 100, thereby improving the reflective visibility of the display apparatus 100. The polarizer 140 can be formed as a film with a polarizing function.

The cover glass 150 can be disposed on the polarizer 140. The cover glass 150 can play a role of protecting elements inside the display panel 130. The cover glass 150 can be formed of glass or plastic and can be transparent.

The adhesive layer 160 can be disposed between the support layer 110 and the back plate 120, between the back plate 120 and the display panel 130, between the display panel 130 and the polarizer 140, and between the polarizer 140 and the cover glass 150.

The adhesive layer 160 can play a role of adhering respective layers of the display apparatus 100 to each other. The adhesive layer 160 can be, for example, optically clear adhesive (OCA) or pressure sensitive adhesive (PSA), but is not limited to either one.

The adhesive layer 160 can be cured through a heat curing process. The heat curing process can proceed for 50 minutes at 110° C. or for 120 minutes at 80°° C. However, the present disclosure is not limited thereto.

The display apparatus 100 can include a bending area BA and a non-bending area NBA.

The bending area BA means an area where at least a part of the display apparatus 100 is bent. The non-bending area NBA means an area where the display apparatus 100 is not bent.

The non-bending area NBA can include the center area of the display apparatus 100. The bending area BA can be located on both sides of the non-bending area NBA and can include the outer area of the display apparatus 100.

However, the present disclosure is not limited thereto. The bending area BA can include the center area of the display apparatus 100, and the non-bending area NBA can be located on both sides of the bending area BA.

The display apparatus 100 can maintain a flat shape without being bent in the non-bending area NBA. The non-bending area NBA can also be referred to as a flat area.

The display apparatus 100 can be bent at least partially in the bending area BA. When the bending area BA includes the outer area of the display apparatus 100 as illustrated in FIG. 1, the display apparatus 100 can have a structure in which the outer area is bent in a direction parallel to a Z-direction as illustrated in FIG. 1.

The display panel 130 can include a display area in which a plurality of subpixels are disposed and a non-display area which surrounds the display area. The non-display area can also be referred to as a bezel area.

The display area can overlap the non-bending area NBA. The width in an X-direction of the display area can be equal to or larger than the width in the X-direction of the non-bending area NBA.

When the width in the X-direction of the display area is larger than the width in the X-direction of the non-bending area NBA, the display area can include the non-bending area NBA, and can partially overlap also the bending area BA.

The non-display area can overlap the bending area BA at the outer part of the display apparatus 100. The width in the X-direction of the non-display area can be equal to or smaller than the width in the X-direction of the bending area BA.

In the case where the width in the X-direction of the non-display area is equal to or smaller than the width in the X-direction of the bending area BA, when the display apparatus 100 is bent in the direction parallel to the Z-direction as illustrated in FIG. 1, a part of the display panel 130 where the non-display area is located can be entirely bent.

Therefore, when viewing the display apparatus 100 in the Z-direction, the non-display area may not be visible.

When implementing the display apparatus 100 in which both the outer areas are bent as illustrated in FIG. 1, because the non-display area is located within the bending area BA, by bending the display apparatus 100, the non-display area can be caused to be invisible without reducing the width of the non-display area. Accordingly, the ratio of the display area, for example, an area where an image is implemented in the display apparatus 100, can be maximized.

In order to implement the display apparatus 100 in which both outer areas are bent, it is necessary to maintain the bent state of the display apparatus 100 after the display apparatus 100 is bent.

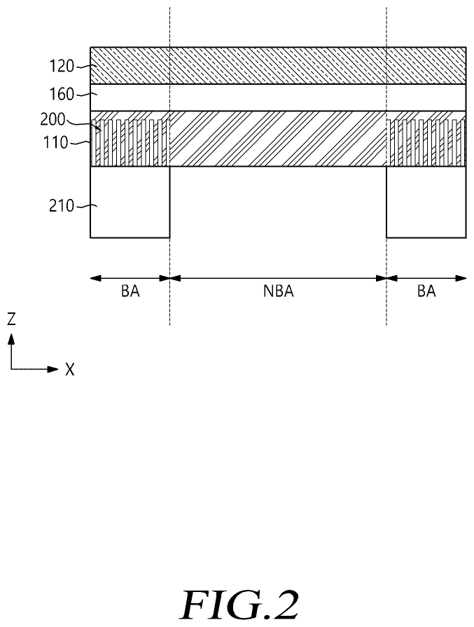

FIG. 2 is a view illustrating a part of the cross-sectional structure illustrated in FIG. 1.

Referring to FIG. 2, the support layer 110 can include a plurality of grooves 200 in an area where the support layer 110 overlaps the bending area BA.

When the support layer 110 includes the plurality of grooves 200, the support layer 110 can be bent more easily in an area where the plurality of grooves 200 are disposed than in an area where the plurality of grooves 200 are not disposed. In addition, as the plurality of grooves 200 are disposed, it is possible to prevent, to some extent, wrinkles from occurring in a process in which the display apparatus 100 is bent.

An adhesive material 210 can be further disposed under the support layer 110. The adhesive material 210 can play a role of adhering materials located around the adhesive material 210 to each other. The adhesive material 210 can be the same material as the adhesive layer 160, but is not limited thereto.

Both the adhesive material 210 and the adhesive layer 160 can be thermosetting materials.

When the display apparatus 100 is bent in the bending area BA, the adhesive material 210 can be absorbed into the plurality of grooves 200.

When heat is applied to the adhesive material 210 absorbed into the plurality of grooves 200 for a specific time at a specific temperature, the adhesive material 210 can be cured. For example, in order to cure the adhesive material 210, heat can be applied for 50 minutes at 110° C. or for 120 minutes at 80°° C. However, the present disclosure is not limited thereto.

The adhesive force of the heat-cured adhesive material 210 can increase. When the adhesive force of the adhesive material 210 increases, the adhesive material 210 can prevent the support layer 110 from being deformed inside the plurality of grooves 200. Accordingly, the support layer 110 can maintain a bent state in the bending area BA.

That is to say, as illustrated in FIG. 2, as the support layer 110 includes the plurality of grooves 200, the display apparatus 100 can be easily bent in the bending area BA, and can maintain a bent structure by a process of heat-curing each of the adhesive layer 160 and the adhesive material 210.

However, when the support layer 110 is formed of metal, a spring-back phenomenon can occur, in which the bent part of the support layer 110 is willing to return to its original flat shape due to restoring force.

When the spring-back phenomenon occurs, the support layer 110 does not maintain a bent structure and springs back to become straightened again.

However, since the adhesive layer 160 disposed on the support layer 110 still maintains a bent structure, the support layer 110 can be separated from the adhesive layer 160. In addition, due to a separation space, bubbles can be generated inside the display apparatus 100.

In other words, as components in the display apparatus 100 are separated from each other, a limitation can arise in relation with the reliability of the display apparatus.

In addition, in order to control wrinkles that are likely to occur when the display apparatus 100 is bent, the process of forming the plurality of grooves 200 in parts of the support layer 110 and attaching and heat-curing the separate adhesive material 210 as described above are necessary, but there is a disadvantage in that the process is complicated and takes a lot of time.

Hereinbelow, measures capable of solving these problems or limitations will be described with reference to the drawings.

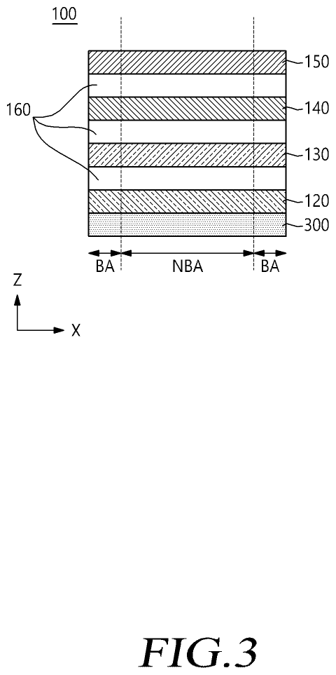

FIG. 3 is a view illustrating another example of the cross-sectional structure of the display apparatus according to the embodiments of the present disclosure.

The cross-sectional structure of the display apparatus 100 illustrated in FIG. 3 is the same as the cross-sectional structure of the display apparatus 100 illustrated in FIG. 1 except that a support member 300 instead of the support layer 110 is disposed under the back plate 120 and there is no adhesive layer 160 under the back plate 120, and thus, repeated description will be omitted or may be briefly provided.

Referring to FIG. 3, the support member 300 can be disposed under the back plate 120.

The support member 300 can be directly attached to the back plate 120. The upper surface of the support member 300 can contact the lower surface of the back plate 120.

The support member 300 can be a fiber reinforced plastic (FRP) prepreg which is made by impregnating a plurality of fiber bundles with a resin to surround the plurality of fiber bundles.

The plurality of fiber bundles can include glass fiber, carbon fiber or aramid fiber, but are not limited thereto.

The resin can include a urethane-based resin. Urethane resin can be heat-cured in a short time at a relatively low temperature compared to epoxy resin. For example, urethane resin can be heat-cured for a time equal to or shorter than 30 minutes at a temperature equal to or lower than 100° C.

When the support member 300 includes urethane resin, since low-temperature curing and rapid curing are possible, there is an advantage in that heat forming can be performed after the support member 300 is attached to the back plate 120.

The support member 300 can be a fabric type prepreg. In the fabric type prepreg, the plurality of fiber bundles can have a woven form. Namely, among the plurality of fiber bundles included in the support member 300, fibers arranged in one direction and fibers arranged in another direction perpendicular to the one direction can be arranged to intersect each other. The plurality of fiber bundles included in the support member 300 can have different patterns in the non-bending area and the bending area. That means the plurality of fiber bundles are woven to have a first pattern in the non-bending area and are woven to have a second pattern in at least a partial area of the bending area. Thus, a different bending behavior can be achieved.

The different first and second pattern are created by different density and/or weaving of the fiber bundles.

So, the plurality of fiber bundles included in the support member 300 may have weave forms depending on a location. The fact that the plurality of fiber bundles included in the support member 300 have different weave forms depending on a location will be described later.

The support member 300 can further include a tackifier. The tackifier can increase the tack force of the support member 300. The tackifier can be a compound, for example, such as cyclopentadiene, cyclopentene, styrene and indene, but is not limited thereto.

The tackifier can be mixed with the resin. In the process of manufacturing the support member 300 by impregnating the plurality of fiber bundles with the resin, the resin can be impregnated into the plurality of fiber bundles in the form of a mixture mixed with the tackifier.

The support member 300 including the tackifier can have a large tack force. For example, the tack force of the support member 300 in which the tackifier is included can be 25 gf/inch or more.

Since the support member 300 has a tack force as the support member 300 includes the tackifier, the support member 300 can be attached to the back plate 120 without a separate adhesive layer.

Since the support member 300 can be attached to the underside of the back plate 120 without a separate adhesive layer, the display apparatus 100 including the support member 300 can be manufactured with a thinner thickness.

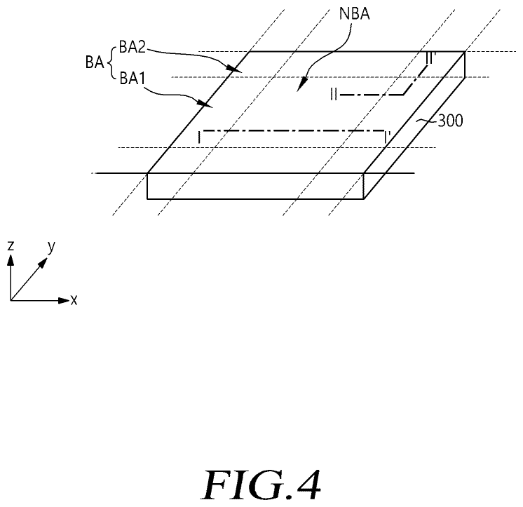

FIG. 4 is a view three-dimensionally illustrating a part of the cross-sectional structure illustrated in FIG. 3.

Referring to FIG. 4, the support member 300 can include the bending area BA and the non-bending area NBA.

As described above, in the non-bending area NBA, the support member 300 is not bent and can maintain a flat shape. So, the central or middle portion is not bent.

The bending area BA can surround the non-bending area NBA on a plane that is defined by the X-direction and a Y-direction. The bending area BA in FIG. 4 fully surrounds the non-bending area NBA, however, it is not limited to that and it is also possible that the bending area BA only partly surrounds the non-bending area NBA, i.e. on one, two or only three side or on two opposing sides.

In the bending area BA, the support member 300 can be bent in a direction parallel to the Z-direction, i.e. up or down.

The bending area BA can include a plurality of first bending areas BA1 and a plurality of second bending areas BA2.

The first bending area BA1 can mean an area which is adjacent to an edge of the non-bending area NBA in the bending area BA.

The second bending area BA2 can mean an area which is adjacent to a point where edges of the non-bending area NBA intersect in the bending area BA. The second bending area BA2 can also be referred to as a corner area. So, the second bending area BA2 does not have a side adjacent to the non-bending area NBA. Only one corner of the second bending area BA2 is adjacent to a corner of the non-bending area NBA.

The plurality of fiber bundles included in the support member 300 can have different weave forms or different densities in the non-bending area NBA, the first bending area BA1 and the second bending area BA2, respectively.

Hereafter, various examples in which weave forms or densities of the plurality of fiber bundles included in the support member 300 are different will be described.

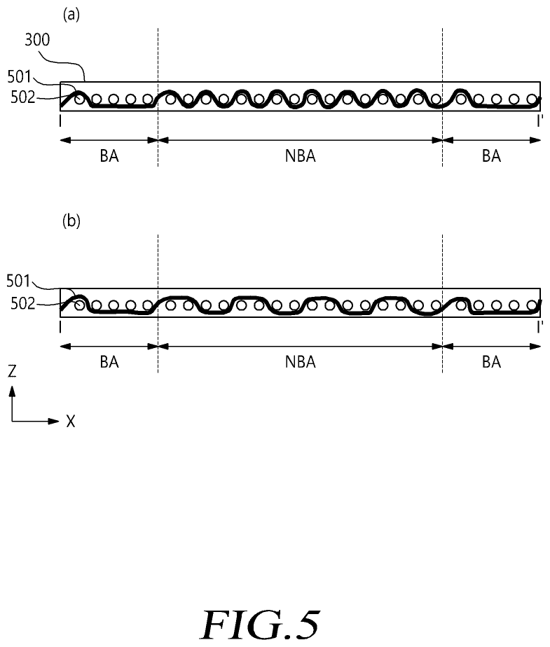

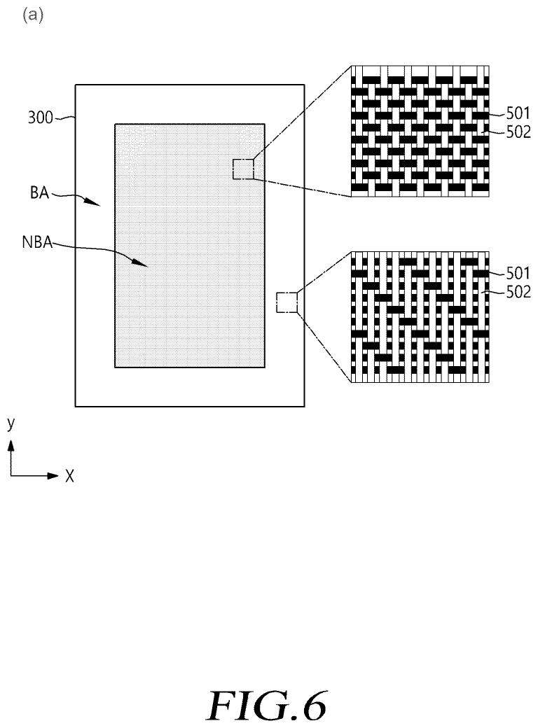

FIG. 5 is a view illustrating an example of a cross-sectional structure taken along a line I-I′ of FIG. 4. FIG. 6 is a view illustrating an example of the planar structure of a configuration illustrated in (a) of FIG. 5.

Referring to FIGS. 5 and 6, the plurality of fiber bundles included in the support member 300 can include fibers 501 arranged in the X-direction (hereinafter referred to as ‘x1 fibers’) and fibers 502 arranged in the Y-direction (hereinafter referred to as ‘y1 fibers’).

The support member 300 can be a single layer of prepreg which includes the plurality of fiber bundles and the resin.

Specifically, the x1 fibers 501 and the y1 fibers 502 can be arranged in one layer as illustrated in FIG. 5. That is to say, all of the x1 fibers 501 can be arranged in the same layer, and all of the y1 fibers 502 can be arranged in the same layer.

The support member 300 can include areas where the x1 fibers 501 and the y1 fibers 502 are disposed to overlap each other and areas where the x1 fibers 501 and the y1 fibers 502 do not overlap each other.

The resin can be disposed to be filled between the plurality of fiber bundles.

Referring to (a) of FIG. 5, the plurality of fiber bundles can have a plain weave form in the non-bending area NBA, and can have a satin weave form in the bending area BA.

The number of intersections of the fibers is less in the bending area BA compared to the non bending area.

In the non-bending area NBA, the x1 fibers 501 and the y1 fibers 502 can be disposed to intersect each other. A point where the x1 fiber 501 and the y1 fiber 502 intersect can appear every one fiber.

In the bending area BA, the x1 fibers 501 and the y1 fibers 502 can be disposed to intersect each other. A point where the x1 fiber 501 and the y1 fiber 502 intersect can appear every four fibers.

The x1 fibers 501 arranged in the bending area BA can be connected to the x1 fibers 501 arranged in the non-bending area NBA. Similarly, the y1 fibers 502 arranged in the bending area BA can be connected to the y1 fibers 502 arranged in the non-bending area NBA.

Referring to (b) of FIG. 5, the plurality of fiber bundles can have a twill weave form in the non-bending area NBA, and can have a satin weave form in the bending area BA.

As described above, in the non-bending area NBA, the x1 fibers 501 and the y1 fibers 502 can be disposed to intersect each other. A point where the x1 fiber 501 and the y1 fiber 502 intersect can appear every two fibers.

Thus, the number of intersections of the fibers is less in the bending area BA resulting in higher flexibility.

In the bending area BA, the x1 fibers 501 and the y1 fibers 502 can be disposed to intersect each other. A point where the x1 fiber 501 and the y1 fiber 502 intersect can appear every four fibers.

As described above, the x1 fibers 501 arranged in the bending area BA can be connected to the x1 fibers 501 arranged in the non-bending area NBA, and the y1 fibers 502 arranged in the bending area BA can be connected to the y1 fibers 502 arranged in the non-bending area NBA.

In FIG. 5, a case where the plurality of fiber bundles have a twill or plain weave form in the non-bending area NBA and have a satin weave form in the bending area BA is illustrated. However, the present disclosure is not limited thereto, and the plurality of fiber bundles can have a plain or twill weave form in some areas of the bending area BA which are adjacent to the non-bending area NBA. Alternatively, the plurality of fiber bundles can have a satin weave form in some areas of the non-bending area NBA which are adjacent to the bending area BA.

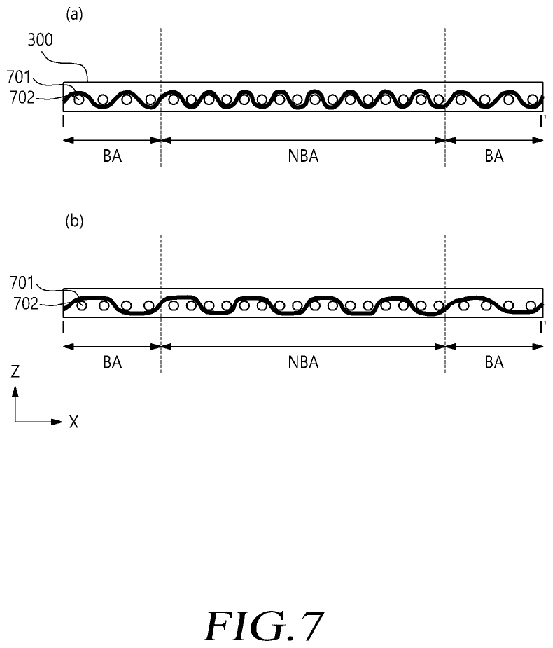

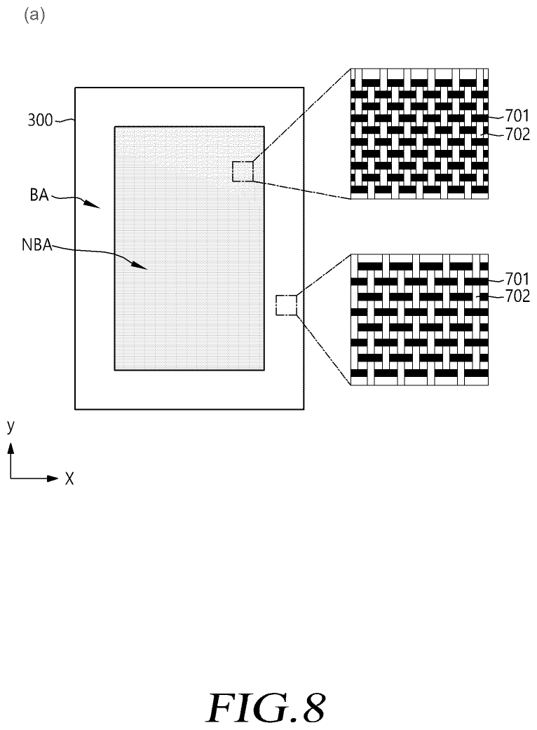

FIG. 7 is a view illustrating another example of the cross-sectional structure taken along the line I-I′ of FIG. 4. FIG. 8 is a view illustrating an example of the planar structure of a configuration illustrated in (a) of FIG. 7.

In the following description, content overlapping the content described above with reference to FIGS. 5 and 6 will be omitted or may be briefly provided.

Referring to FIGS. 7 and 8, the plurality of fiber bundles included in the support member 300 can include fibers 701 arranged in the X-direction (hereinafter referred to as ‘x2 fibers’) and fibers 702 arranged in the Y-direction (hereinafter referred to as ‘y2 fibers’).

Referring to (a) and (b) of FIG. 7, the plurality of fiber bundles can have the same weave form in the bending area BA and the non-bending area NBA. For example, the plurality of fiber bundles can have a plain weave form or a twill weave form in both the bending area BA and the non-bending area NBA.

Referring to (a) of FIG. 7 and FIG. 8, the x2 fibers 701 and the y2 fibers 702 can be arranged more densely in the non-bending area NBA than in the bending area BA. The distance between the x2 fibers 701 or the distance between the y2 fibers 702 can be larger in the bending area BA than in the non-bending area NBA.

The density of the plurality of fiber bundles included in the support member 300 can be smaller in the bending area BA than in the non-bending area NBA.

Specifically, in the non-bending area NBA, the support member 300 can have a porosity of 3% or less. A porosity can mean the ratio of an area in which the x2 fibers 701 and the y2 fibers 702 are not disposed in an area where the plurality of fiber bundles are disposed.

In the bending area BA, the support member 300 can have a porosity of 3% or more and 11% or less. In other words, an area where the x2 fibers 701 and the y2 fibers 702 are not disposed can be larger in the bending area BA than in the non-bending area NBA.

The x2 fibers 701 arranged in the bending area BA can be connected to the x2 fibers 701 arranged in the non-bending area NBA. Similarly, the y2 fibers 702 arranged in the bending area BA can be connected to the y2 fibers 702 arranged in the non-bending area NBA.

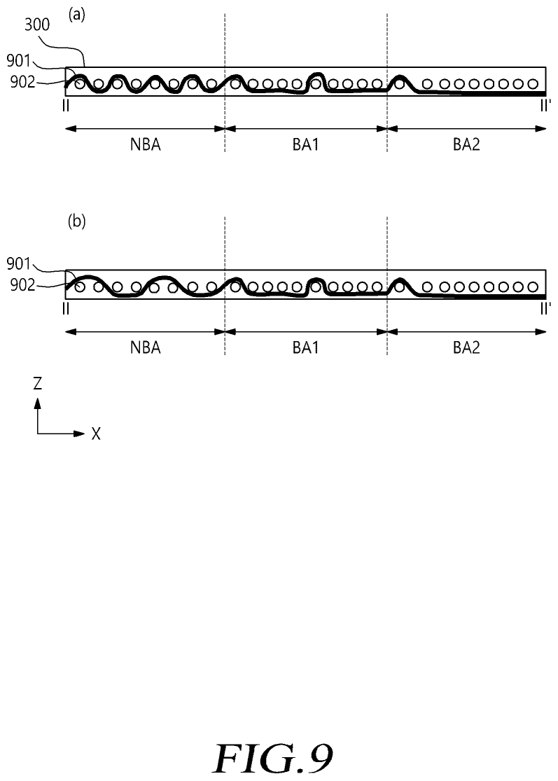

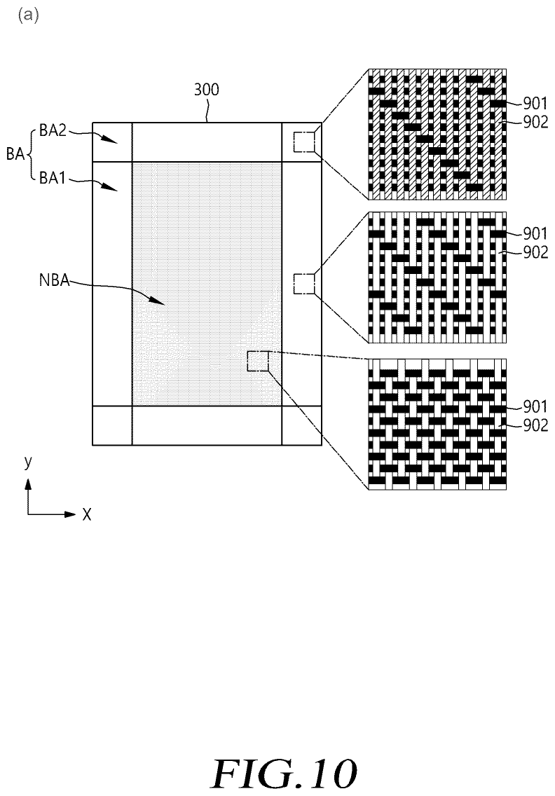

FIG. 9 is a view illustrating an example of a cross-sectional structure taken along a line II-II′ of FIG. 4. FIG. 10 is a view illustrating an example of the planar structure of a configuration illustrated in (a) of FIG. 9.

In the following description, content overlapping the content described above with reference to FIGS. 5 to 8 will be omitted or may be briefly provided.

Referring to FIGS. 9 and 10, the plurality of fiber bundles included in the support member 300 can include fibers 901 arranged in the X-direction (hereinafter referred to as ‘x3 fibers’) and fibers 902 arranged in the Y-direction (hereinafter referred to as ‘y3 fibers’).

The plurality of fiber bundles can have different weave forms in the non-bending area NBA, the first bending area BA1 and the second bending area (or the corner area) BA2.

Referring to (a) and (b) of FIG. 9, the plurality of fiber bundles can have a plain or twill weave form in the non-bending area NBA, and can have a satin weave form in the first bending area BA1 and the second bending area BA2.

Among the plurality of fiber bundles, the fibers arranged in the first bending area BA1 can have a satin weave form in which the x3 fibers 901 and the y3 fibers 902 intersect every four fibers, and the fibers arranged in the second bending area BA2 can have a satin weave form in which the x3 fibers 901 and the y3 fibers 902 intersect every eight fibers.

The x3 fibers 901 arranged in the non-bending area NBA can be connected to the x3 fibers 901 arranged in the first bending area BA1. The x3 fibers 901 arranged in the first bending area BA1 can be connected to the x3 fibers 901 arranged in the second bending area BA2. Similarly, the y3 fibers 902 arranged in the non-bending area NBA can be connected to the y3 fibers 902 arranged in the first bending area BA1. The y3 fibers 902 arranged in the first bending area BA1 can be connected to the y3 fibers 902 arranged in the second bending area BA2.

In FIG. 9, a case where the plurality of fiber bundles have a plain or twill weave form in the non-bending area NBA and a satin weave form in the first bending area BA1 and the second bending area BA2 is illustrated. However, the present disclosure is not limited thereto, and the plurality of fiber bundles can have a plain or twill weave form in some areas of the first bending area BA1 which are adjacent to the non-bending area NBA. Alternatively, the plurality of fiber bundles can have a satin weave form in some areas of the non-bending area NBA which are adjacent to the first bending area BA1.

Similarly, in some areas of the second bending area BA2 which are adjacent to the first bending area BA1, the plurality of fiber bundles can have a satin weave form in which the x3 fibers 901 and the y3 fibers 902 intersect every four fibers. Alternatively, in some areas of the first bending area BAI which are adjacent to the second bending area BA2, the plurality of fiber bundles can have a satin weave form in which the x3 fibers 901 and the y3 fibers 902 intersect every eight fibers.

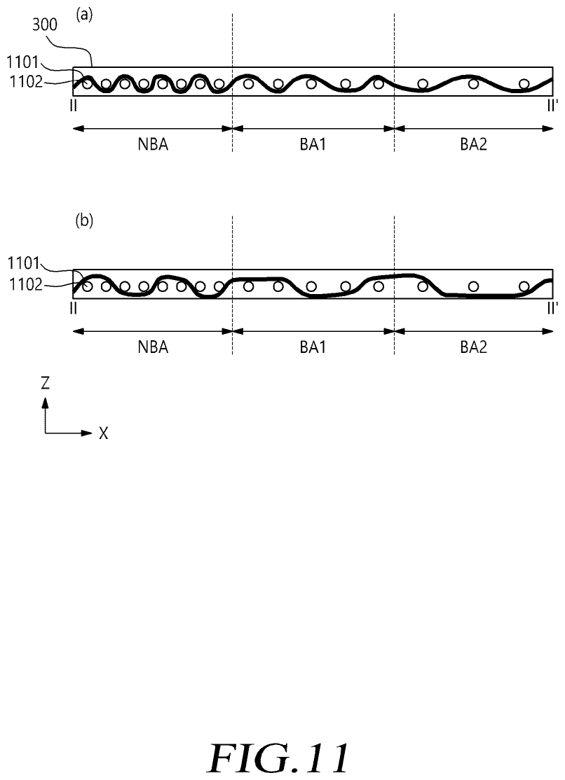

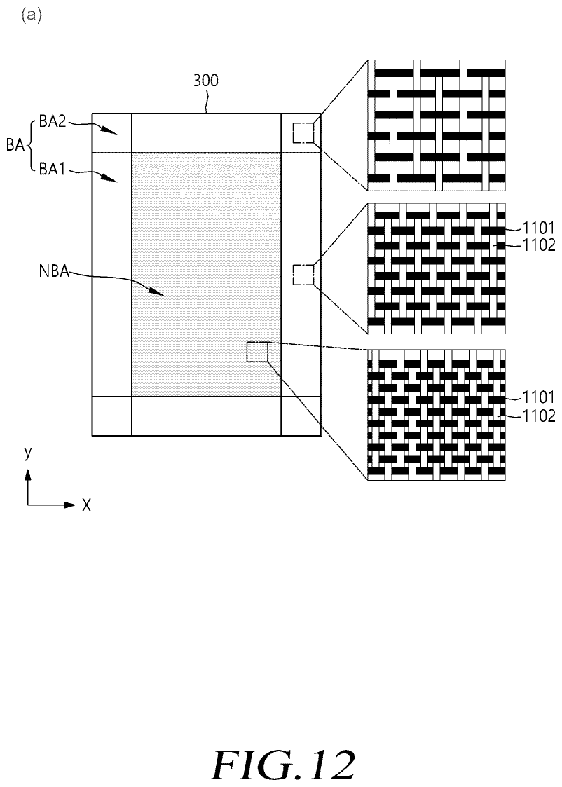

FIG. 11 is a view illustrating another example of the cross-sectional structure taken along the line II-II' of FIG. 4. FIG. 12 is a view illustrating an example of the planar structure of a configuration illustrated in (a) of FIG. 11.

In the following description, content overlapping the content described above with reference to FIGS. 9 and 10 will be omitted or may be briefly provided.

Referring to FIGS. 11 and 12, the plurality of fiber bundles included in the support member 300 can include fibers 1101 arranged in the X-direction (hereinafter referred to as ‘x4 fibers’) and fibers 1102 arranged in the Y-direction (hereinafter referred to as ‘y4 fibers’).

Referring to (a) and (b) of FIG. 11, the plurality of fiber bundles can have the same weave form in the non-bending area NBA, the first bending area BA1 and the second bending area BA2. For example, all of the plurality of fiber bundles can have a plain weave form or a twill weave form in the first bending area BA1, the second bending area BA2 and the non-bending area NBA.

Referring to (a) of FIG. 11 and FIG. 12, the x4 fibers 1101 and the y4 fibers 1102 can be arranged more densely in the first bending area BA1 than in the second bending area BA2, and can be arranged more densely in the non-bending area NBA than in the first bending area BA1.

The distance between the x4 fibers 1101 or the distance between the y4 fibers 1102 can be larger in the first bending area BA1 than in the non-bending area NBA, and can be larger in the second bending area BA2 than in the first bending area BA1.

The density of the plurality of fiber bundles included in the support member 300 can be smaller in the first bending area BA1 than in the non-bending area NBA, and can be smaller in the second bending area BA2 than in the first bending area BA1.

Specifically, in the non-bending area NBA, the support member 300 can have a porosity of 3% or less. In the first bending area BA1, the support member 300 can have a porosity of 3% or more and 5% or less. In the second bending area BA2, the support member 300 can have a porosity of 5% or more and 11% or less. Namely, an area where the x4 fibers 1101 and the y4 fibers 1102 are not disposed can be larger in the first bending area BA1 than in the non-bending area NBA, and can be larger in the second bending area BA2 than in the first bending area BA1.

In the plurality of fiber bundles described with reference to FIGS. 5 to 12, the distance between intersections of intersecting fibers can be shortest in the non-bending area NBA. Alternatively, x fibers and y fibers can be most densely arranged in the non-bending area NBA.

The distance between intersections of intersecting fibers can be longer in the bending area BA than in the non-bending area NBA. Alternatively, x fibers and y fibers can be arranged at a lower density in the bending area BA than in the non-bending area NBA.

In particular, in the second bending area BA2 of the bending areas BA which is adjacent to the area where the edges of the non-bending area NBA intersect, the distance between intersections of intersecting fibers can be longer than in the first bending area BA1. Alternatively, x fibers and y fibers can be arranged at a lower density in the second bending area BA2 than in the first bending area BA1.

As described with reference to FIGS. 5, 6, 9 and 10, when the distance between intersections of intersecting fibers in the bending area BA is larger than that in the non-bending area NBA, for example, when the plurality of fiber bundles have a satin weave form in the bending area BA, fibers can move more freely than when the plurality of fiber bundles have a plain or twill weave form. Accordingly, when the display apparatus 100 is bent, fibers can easily move to fit a bent shape, and thus, it is possible to prevent the shape of the support member 300 from being deformed due to bending.

Therefore, a limitation that wrinkles may occur when the display apparatus 100 is bent in the bending area BA can be solved, prevented or minimized.

Moreover, when the distance between intersections of intersecting fibers is longer in the corner area, for example, the second bending area BA2, than in the first bending area BA1, fibers can move more easily according to the structural deformation of the support member 300, and thus, a limitation that wrinkles may occur can be solved, prevented or minimized even in the corner area where wrinkles are most likely to occur when the display apparatus 100 is bent.

As described with reference to FIGS. 7, 8, 11 and 12, when the density of the plurality of fiber bundles is smaller in the bending area BA than in the non-bending area NBA, the disposition of fibers becomes loose and the distance between intersections of intersecting fibers becomes longer, and thus respective fibers can move more freely. Therefore, when the display apparatus 100 is bent, fibers can easily move to fit a bent shape, and thus, it is possible to prevent the shape of the support member 300 from being deformed when the display apparatus 100 bent.

Therefore, a limitation that wrinkles may occur when the display apparatus 100 is bent in the bending area BA can be solved, prevented or minimized.

Moreover, when the density of the plurality of fiber bundles is smaller in the corner area, for example, the second bending area BA2, than in the first bending area BA1, fibers can move more easily according to the structural deformation of the support member 300, and thus, a limitation that wrinkles may occur in the corner area can be solved, prevented or minimized. In addition, as described above, when using the support member 300 in which at least one of a weave form or the density of fibers in the bending area BA is different from a weave form or the density of fibers in the non-bending area NBA, the wrinkles of the display apparatus 100 can be controlled even without performing a micro-patterning process in which a plurality of grooves are formed in the support member 300 and an adhesive material is used and cured.

Furthermore, when the support member 300 including not metal but the plurality of fiber bundles and the resin is attached to the back plate 120, a spring-back phenomenon does not occur, and thus, it is possible to prevent or minimize a limitation that the support member 300 is separated from the back plate 120 or bubbles are generated in a separation space.

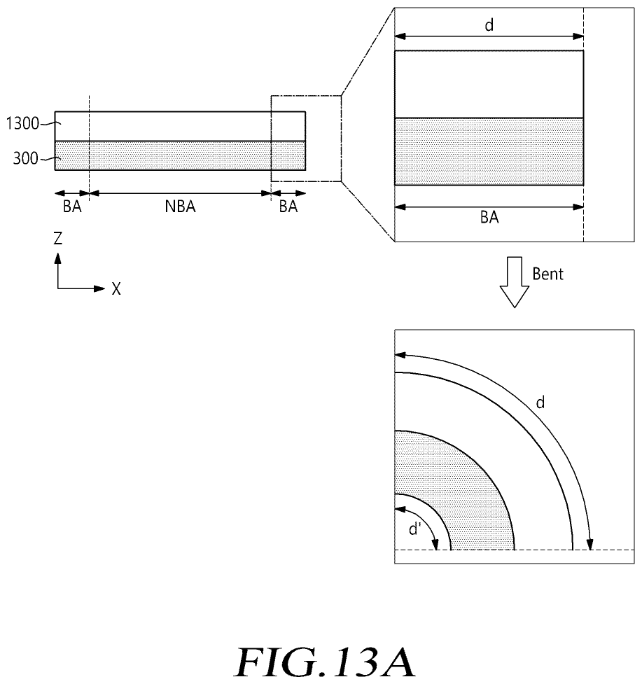

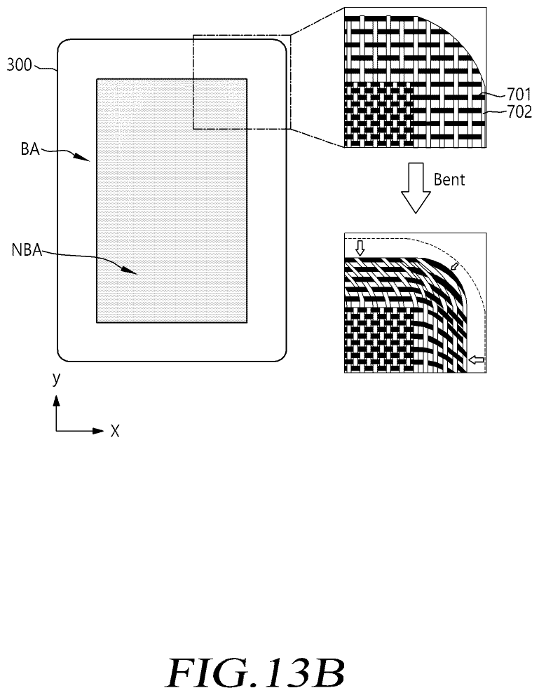

FIGS. 13A and 13B are views illustrating examples of changes in the cross-sectional and planar structures of the display apparatus when the display apparatus is bent.

Referring to FIG. 13A, the display apparatus 100 can include the support member 300 and an upper layer 1300 which is disposed on the support member 300.

The upper layer 1300 can include a back plate, a display panel, a polarizer, a cover glass and an adhesive layer.

The widths in the X-direction of the upper layer 1300 and the support member 300 in the bending area BA can both be d.

In the bending area BA, the upper layer 1300 and the support member 300 can be bent in the direction parallel to the Z-direction.

The upper layer 1300 can maintain a constant width in the bending area BA even when bending occurs. When the width of the upper layer 1300 in the bending area BA is constantly maintained, a change in optical performance due to bending can be minimized.

However, in order for the display apparatus 100 to have a bent structure even without the width of the upper layer 1300 changed as illustrated in FIG. 13A, the support member 300 should be easily compressible. That is to say, when bending occurs, a width d′ of the support member 300 in the bending area BA can become smaller than the width d of the upper layer 1300 in the bending area BA.

In order for the support member 300 to be easily compressed and be changed in its width, fibers included in the support member 300 should be able to move freely.

Referring to FIG. 13B, the support member 300 can include the x2 fibers 701 and the y2 fibers 702.

Both the x2 fibers 701 and the y2 fibers 702 can have a plain weave form as described above as an example with reference to FIG. 8. However, the present disclosure is not limited thereto, both the x2 fibers 701 and the y2 fibers 702 can have a twill weave form. Alternatively, the x2 fibers 701 can have a plain or twill weave form, and the y2 fibers 702 can have a satin weave form.

As described above, the x2 fibers 701 and the y2 fibers 702 can be arranged more densely in the non-bending area NBA than in the bending area BA. The distance between the x2 fibers 701 or the distance between the y2 fibers 702 can be larger in the bending area BA than in the non- bending area NBA.

The support member 300 can be bent at least partially in the Z-direction in the bending area BA.

As the support member 300 is bent in the Z-direction, each of the distance between the x2 fibers 701 and the distance between the y2 fibers 702 can become smaller than before the support member 300 is bent. In other words, pores existing between the x2 fibers 701 or the y2 fibers 702 can be reduced.

As illustrated in FIG. 13B, since the distance between the x2 fibers 701 or the distance between the y2 fibers 702 is formed relatively longer in the bending area BA than in the non-bending area NBA, even when the support member 300 is bent, the x2 fibers 701 and the y2 fibers 702 in the bending area BA can move more freely than in the non-bending area NBA. For example, when bending occurs, the x2 fibers 701 and the y2 fibers 702 in the bending area BA can freely move to adjacent x2 fibers 701 and y2 fibers 702, or the lengths of the x2 fibers 701 and y2 fibers 702 in the bending area BA can easily decrease or increase compared to the x2 fibers 701 and y2 fibers 702 in the non-bending area NBA.

Since fibers located in the bending area BA can more easily move or be freely deformed such as by being stretched or shrinking compared to fibers located in the non-bending area NBA, even when bending occurs in the support member 300, wrinkles that can occur in the outer or corner area of the bending area BA can be effectively controlled.

Hereunder, a method for manufacturing a display apparatus according to embodiments of the present disclosure will be described.

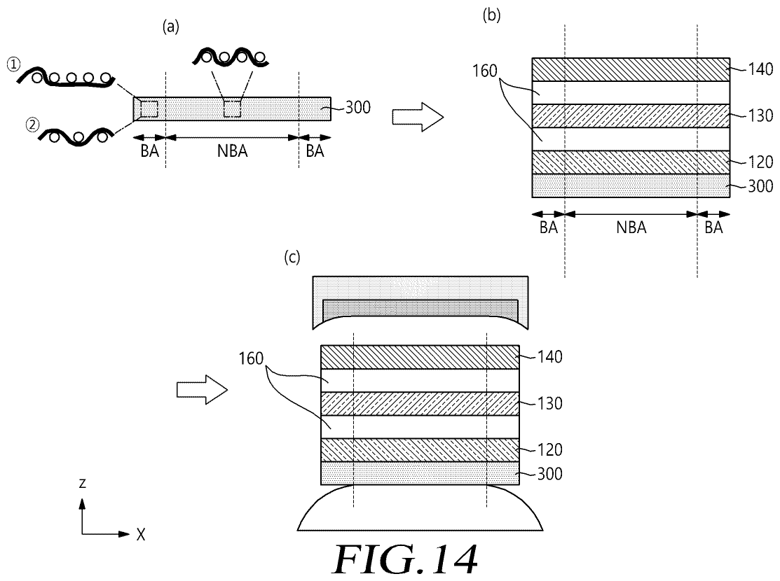

FIG. 14 is a view illustrating an example of a method for manufacturing a display apparatus according to embodiments of the present disclosure.

Referring to (a) of FIG. 14, a plurality of fiber bundles can be woven to have a plain weave form in the non-bending area NBA and to have a satin weave form like (1) in the bending area BA or to have a plain weave form in the bending area BA but be arranged at a lower density in the bending area BA than fibers in the non-bending area NBA like (2).

In (a) of FIG. 14, a case where the plurality of fiber bundles have a plain weave form in the non-bending area NBA is illustrated. However, the present disclosure is not limited thereto, and the plurality of fiber bundles can have a twill weave form in the non-bending area NBA.

The plurality of fiber bundles which are woven can be impregnated with resin. The resin can include a urethane-based resin.

The resin can include a tackifier. As described above, the tackifier can be a compound such as cyclopentadiene, cyclopentene, styrene and indene, but is not limited thereto.

The resin including the tackifier can be impregnated into the plurality of fiber bundles which are woven.

Referring to (b) of FIG. 14, the plurality of fiber bundles impregnated with the resin or the support member 300 can be attached to the underside of the back plate 120 of the display apparatus 100.

Since the support member 300 has a tack force, the support member 300 can be directly attached to the lower surface of the back plate 120 without a separate adhesive layer.

After the support member 300 is directly attached to the lower surface of the back plate 120, the outer area of the display apparatus 100 can be removed by laser trimming.

Since a laser trimming process is performed after the support member 300 is attached to the back plate 120, the width in the X-direction of the support member 300 after the laser trimming process can be equal to the width in the X-direction of the back plate 120 or the width in the X-direction of the display panel 130.

Referring to (c) of FIG. 14, the laser-trimmed display apparatus 100 can be formed to be bent in the bending area BA.

The display apparatus 100 can be formed by a press process and a thermoforming process.

The press process can be a process in which the display apparatus 100 is inserted in molds with curved shapes and is then pressed from above and below the display apparatus 100 to have the same shape as the molds.

The thermoforming process can be performed simultaneously with the press process, and can be a process in which the resin included in the support member 300 is cured by applying heat.

The thermoforming process can proceed for a time equal to or shorter than 30 minutes at a temperature equal to or lower than 100° C.

For example, the thermoforming process can proceed for 5 minutes at 100° C. or for 20 minutes at 90° C., but is not limited thereto.

The display apparatus 100 can have a bent shape in the bending area BA by the press process and the thermoforming process.

The resin included in the support member 300 is cured by the thermoforming process, and the tack force of the support member 300 increases due to curing of the resin. Thus, the support member 300 can be completely attached to the back plate 120, allowing the display apparatus 100 to maintain a bent structure. For example, the fully cured resin can have a tack force equal to or greater than 1000 gf/inch.

The cover glass 150 can be formed on the display apparatus 100 with the bent shape.

The cover glass 150 can be attached to the display apparatus 100 in a shape bent in the same manner as the display apparatus 100. The cover glass 150 can be attached to the polarizer 140 using an adhesive layer.

As the display apparatus 100 is attached to the cover glass 150 in a state in which the display apparatus 100 has the bent shape, it is possible to prevent wrinkles that can occur when attaching the flat display apparatus 100 to the cover glass 150 and then bending the flat display apparatus 100.

As described above, the display apparatus 100 including the support member 300 can implement bending through a single thermoforming process.

On the other hand, in the display apparatus 100 described above with reference to FIG. 2, since both the adhesive layer 160 and the adhesive material 210 should be cured in order to implement bending, two thermoforming processes are required. Therefore, when the display apparatus 100 includes the support member 300, a process can be simplified.

In addition, because the support member 300 does not require a separate adhesive layer, a separate attachment process is not required when connecting the back plate 120 and the support member 300, and thus, the process can be further simplified.

Moreover, since the support member 300 includes a urethane-based resin, a curing time is shortened, and thus, process efficiency can be increased.

Brief description of the embodiments of the present disclosure described above is as follows.

According to embodiments of the present disclosure, a display apparatus can include a display panel including a non-bending area and a bending area which surrounds the non-bending area; and a support member located below the display panel and including a plurality of fiber bundles and a resin which surrounds the plurality of fiber bundles, wherein the plurality of fiber bundles are woven to have a first pattern in the non-bending area and are woven to have a second pattern in at least a partial area of the bending area and at least one of a weave form or a fiber density of the first pattern is different from at least one of a weave form or a fiber density of the second pattern.

In the display apparatus according to the embodiments of the present disclosure, the first pattern can be a plain weave form or a twill weave form, and the second pattern can be a satin weave form.

In the display apparatus according to the embodiments of the present disclosure, the first pattern and the second pattern can be a plain weave form or a twill weave form, and a density of the plurality of fiber bundles included in the second pattern can be lower than a density of the plurality of fiber bundles included in the first pattern.

In the display apparatus according to the embodiments of the present disclosure, the support member can be woven to have, in at least another partial area of the bending area, a third pattern different from at least one of the weave form or the fiber density of the second pattern.

In the display apparatus according to the embodiments of the present disclosure, the second pattern can be located adjacent to an edge portion of the bending area, and the third pattern can be located adjacent to an intersection area of edge portions of the bending area.

In the display apparatus according to the embodiments of the present disclosure, at least one of a weave form or a fiber density of the third pattern can be different from at least one of the weave form or the fiber density of the first pattern.

In the display apparatus according to the embodiments of the present disclosure, the first pattern can be a plain weave form or a twill weave form and the second pattern and the third pattern can be a satin weave form, and the third pattern can have a longer length between intersections of the plurality of fiber bundles than the second pattern.

In the display apparatus according to the embodiments of the present disclosure, the first pattern, the second pattern and the third pattern can be a plain weave form or a twill weave form, and densities of the plurality of fiber bundles included in the first pattern, the second pattern and the third pattern can gradually decrease in the order of the first pattern, the second pattern and the third pattern.

In the display apparatus according to the embodiments of the present disclosure, the display apparatus can further include a back plate disposed between the display panel and the support member, wherein the support member can contact a lower surface of the back plate.

In the display apparatus according to the embodiments of the present disclosure, the support member can further include a tackifier.

In the display apparatus according to the embodiments of the present disclosure, the support member can be a single layer of prepreg.

In the display apparatus according to the embodiments of the present disclosure, a width in a horizontal direction of the support member can be equal to a width in the horizontal direction of the display panel.

In the display apparatus according to the embodiments of the present disclosure, the resin can include urethane resin.

According to embodiments of the present disclosure, a display apparatus can include a display panel including a first area and a second area which surrounds the first area; and a support member disposed on a back surface of the display panel and including a plurality of fiber bundles, wherein the plurality of fiber bundles are woven in a first pattern in an area overlapping the first area and are woven in a second pattern different from the first pattern in an area overlapping at least a part of the second area.

In the display apparatus according to the embodiments of the present disclosure, the first area can be flat, and at least a part of the second area can be bent.

In the display apparatus according to the embodiments of the present disclosure, the first pattern can be a plain weave form or a twill weave form, and the second pattern can be a satin weave form.

In the display apparatus according to the embodiments of the present disclosure, the first pattern and the second pattern can be a plain weave form or a twill weave form, and a density of the plurality of fiber bundles included in the second pattern can be lower than a density of the plurality of fiber bundles included in the first pattern.

In the display apparatus according to the embodiments of the present disclosure, the support member can be woven to have a third pattern different from the second pattern in an area overlapping at least another part of the second area.

In the display apparatus according to the embodiments of the present disclosure, the first pattern can be a plain weave form or a twill weave form and the second pattern and the third pattern can be a satin weave form, and the third pattern can have a longer length between intersections of the plurality of fiber bundles than the second pattern.

In the display apparatus according to the embodiments of the present disclosure, the first pattern, the second pattern and the third pattern can be a plain weave form or a twill weave form, and densities of the plurality of fiber bundles included in the first pattern, the second pattern and the third pattern can gradually decrease in the order of the first pattern, the second pattern and the third pattern.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. For example, the disclosed embodiments are intended to illustrate the scope of the technical idea of the present disclosure.

What is claimed is:

1. A display apparatus comprising:
a display panel including a non-bending area and a bending area adjacent to the non-bending area; and
a support member located below the display panel and including a plurality of fiber bundles and a resin surrounding the plurality of fiber bundles,
wherein the plurality of fiber bundles are woven to have a first pattern in the non-bending area and are woven to have a second pattern in at least a partial area of the bending area, and
wherein at least one of a weave form or a fiber density of the first pattern is different from at least one of a weave form or a fiber density of the second pattern.

2. The display apparatus of claim 1, wherein the first pattern is a plain weave form or a twill weave form, and the second pattern is a satin weave form.

3. The display apparatus of claim 1, wherein the first pattern and the second pattern are a plain weave form or a twill weave form, and
wherein a density of the plurality of fiber bundles included in the second pattern is lower than a density of the plurality of fiber bundles included in the first pattern.

4. The display apparatus of claim 1, wherein the support member is woven to have a third pattern, in at least another partial area of the bending area, at least one of the weave form or the fiber density of the third pattern being different from at least one of the weave form or the fiber density of the second pattern.

5. The display apparatus of claim 4, wherein the second pattern is located adjacent to an edge portion of the bending area, and the third pattern is located adjacent to an intersection area of edge portions of the bending area.

6. The display apparatus of claim 4, wherein at least one of a weave form or a fiber density of the third pattern is different from at least one of the weave form or the fiber density of the first pattern.

7. The display apparatus of claim 4, wherein the first pattern is a plain weave form or a twill weave form, and the second pattern and the third pattern are a satin weave form, and wherein the third pattern has a longer length between intersections of the plurality of fiber bundles than the second pattern.

8. The display apparatus of claim 4, wherein the first pattern, the second pattern and the third pattern are a plain weave form or a twill weave form, and
wherein densities of the plurality of fiber bundles included in the first pattern, the second pattern and the third pattern gradually decrease in the order of the first pattern, the second pattern and the third pattern.

9. The display apparatus of claim 1, further comprising:
a back plate disposed between the display panel and the support member, wherein the support member contacts a lower surface of the back plate.

10. The display apparatus of claim 1, wherein the support member further includes a tackifier.

11. The display apparatus of claim 1, wherein a width in a horizontal direction of the support member is equal to a width in the horizontal direction of the display panel.

12. The display apparatus of claim 4, wherein the at least another partial area of the bending area is a corner area.

13. The display apparatus of claim 1, wherein the plurality of fiber bundles include first fibers and second fibers, and
wherein the first fibers arranged in the bending area are connected to the first fibers arranged in the non-bending area, and the second fibers arranged in the bending area are connected to the second fibers arranged in the non-bending area.

14. A display apparatus comprising:
a display panel including a first area and a second area adjacent to the first area; and
a support member disposed on a back surface of the display panel and including a plurality of fiber bundles,
wherein the plurality of fiber bundles are woven in a first pattern in an area overlapping the first area and are woven in a second pattern in an area overlapping at least a part of the second area,
wherein the first pattern and the second pattern are different weave type or the plurality of fiber bundles included in the first pattern and the plurality of fiber bundles included in the second pattern have different density.

15. The display apparatus of claim 14, wherein the first area is flat, and at least a part of the second area is bent.

16. The display apparatus of claim 14, wherein the first pattern is a plain weave form or a twill weave form, and the second pattern is a satin weave form.

17. The display apparatus of claim 14, wherein the first pattern and the second pattern are a plain weave form or a twill weave form, and wherein a density of the plurality of fiber bundles included in the second pattern is lower than a density of the plurality of fiber bundles included in the first pattern.

18. The display apparatus of claim 14, wherein the support member is woven to have a third pattern different from the second pattern in an area overlapping at least another part of the second area.

19. The display apparatus of claim 18, wherein the first pattern is a plain weave form or a twill weave form, and the second pattern and the third pattern are a satin weave form, and wherein the third pattern has a longer length between intersections of the plurality of fiber bundles than the second pattern.

20. The display apparatus of claim 18, wherein the first pattern, the second pattern and the third pattern are a plain weave form or a twill weave form, and wherein densities of the plurality of fiber bundles included in the first pattern, the second pattern and the third pattern gradually decrease in the order of the first pattern, the second pattern and the third pattern.
